(19) United States
(12) Patent Application Publication
(10) Pub. No.: US 2012/0299158 A1
(43) Pub. Date: Nov. 29, 2012

(54) CMP POLISHING LIQUID, METHOD FOR POLISHING SUBSTRATE, AND ELECTRONIC COMPONENT

(75) Inventors: Takashi Shinoda, Ibaraki (JP); Kazuhiro Enomoto, Ibaraki (JP); Toshiaki Akutsu, Ibaraki (JP)

(73) Assignee: HITACHI CHEMICAL COMPANY, LTD., Tokyo (JP)

(21) Appl. No.: 13/265,926

(22) PCT Filed: Dec. 10, 2010
(86) PCT No.: PCT/JP2010/072291

§ 371 Date: Oct. 24, 2011

(30) Foreign Application Priority Data
Dec. 10, 2009 (JP) 2009-280347
Mar. 9, 2010 (JP) 2010-051977

(51) Int. Cl. C09K 13/00; H01L 29/02; H01L 21/304; C09K 13/06; H01L 21/306

(52) U.S. Cl. 257/618; 252/79.1; 252/79.4; 438/693; 257/E21.23; 257/E29.002

(57) ABSTRACT

The CMP polishing liquid of the invention is used by mixing a first solution and a second solution, the first solution comprises cerium-based abrasive grains, a dispersant and water, the second solution comprises a polyacrylic acid compound, a surfactant, a pH regulator, a phosphoric acid compound and water, the pH of the second solution is 6.5 or higher, and the first solution and second solution are mixed so that the phosphoric acid compound content is within a prescribed range. The CMP polishing liquid of the invention comprises cerium-based abrasive grains, a dispersant, a polyacrylic acid compound, a surfactant, a pH regulator, a phosphoric acid compound and water, with the phosphoric acid compound content being within a prescribed range.

### TECHNICAL FIELD

The present invention relates to a CMP polishing liquid, to a method for polishing a substrate and to an electronic component.

### BACKGROUND ART

There is currently a trend toward increasing packaging density in ultra-large-scale integrated circuits, and research and development of various micromachining techniques has been conducted, and the sub-half-micron order is becoming a general design rule. CMP (chemical mechanical polishing) is one technique that has been developed to meet this intense demand for micronization.

CMP technology reduces the burden of exposure technology by accomplishing virtually complete flattening of layer to be exposed in semiconductor device production steps, allowing yields to be stabilized at a high level. Thus, CMP technology is essential for flattening of interlayer insulating films and BPSG films and for shallow trench isolation, for example.

The CMP polishing liquids commonly used at the current time are CMP polishing liquids that are designed primarily for polishing of silicon oxide films, silicon oxide films and polysilicon films typically can be polished at least 5 times faster than silicon nitride films.

On the other hand, no polishing solutions have existed for polishing of silicon nitride films at practical speeds. Some techniques, such as described in Patent document 1, increase the polishing speed for silicon nitride films by addition of phosphoric acid at 1.0 mass % or greater, allowing silicon nitride film polishing steps to be accomplished in a practical manner.

### CITATION LIST

### Patent Literature

[Patent document 1] Japanese Patent Publication No. 3190742

### SUMMARY OF INVENTION

### Technical Problem

A variety of circuit-forming processes employing CMP techniques have been proposed in recent years, one of which is a process in which a silicon oxide film and silicon nitride film are polished and polishing is completed when a polysilicon stopper film has been exposed. More specifically, these include, for example, high-k/metal gate processes (processes in which a silicon oxide film and silicon nitride film are polished and polishing is completed when the polysilicon film is exposed), which are designed for application in 45 nm node and later logic devices.

The technique disclosed in Patent document 1 does not allow realization of such polishing step for polishing of such silicon oxide films and silicon nitride films at a practical polishing speed and for polishing of polysilicon films as stopper films. In addition, the technique disclosed in Patent document 1 cannot be applied in polishing steps for selective polishing of two types of films of silicon oxide film and silicon nitride film, against a polysilicon film.

The present invention provides a CMP polishing liquid that can increase the polishing speed for silicon oxide films and silicon nitride films with respect to the polishing speed for polysilicon films, and that can be applied in a polishing step for polishing of a silicon oxide film and silicon nitride film using a polysilicon film as the stopper film, as well as a method for polishing a substrate using the CMP polishing liquid, and an electronic component comprising a substrate polished by the polishing method.

### Solution to Problem

Specifically, the invention provides a CMP polishing liquid to be used by mixing a first solution and a second solution, the first solution comprising cerium-based abrasive grains, a dispersant and water, the second solution comprising a polyacrylic acid compound, a surfactant, a pH regulator, at least one phosphoric acid compound of phosphoric acid and a phosphoric acid derivative, and water, the pH of the second solution being 6.5 or higher, and the first solution and second solution being mixed so that the phosphoric acid compound content is 0.01-1.0 mass % based on the total mass of the CMP polishing liquid.

The CMP polishing liquid of the invention can increase the polishing speed for silicon oxide films and silicon nitride films with respect to the polishing speed for polysilicon films, and can be applied in a polishing step for polishing of a silicon oxide film and silicon nitride film using a polysilicon film as the stopper film.

The second solution may comprise a basic compound having a pKa of 8 or greater, as the pH regulator.

The second solution preferably comprises a nonionic surfactant as the surfactant. This can further increase the polishing speed for silicon oxide films and silicon nitride films with respect to the polishing speed for polysilicon films.

The pH of the first solution is preferably 7.0 or higher.

The first solution preferably comprises cerium oxide particles as the cerium-based abrasive grains. Also, more preferably, the first solution comprises cerium oxide particles as the cerium-based abrasive grains, wherein the mean particle size of the cerium-based abrasive grains is 0.01-2.0 μm.

The first solution preferably comprises a polyacrylic acid-based dispersant as the dispersant. This can further increase the polishing speed for silicon oxide films and silicon nitride films with respect to the polishing speed for polysilicon films.

The invention further provides a CMP polishing liquid comprising cerium-based abrasive grains, a dispersant, a polyacrylic acid compound, a surfactant, a pH regulator, at least one phosphoric acid compound of phosphoric acid and a phosphoric acid derivative, and water, wherein the phosphoric acid compound content is 0.01-1.0 mass % based on the total mass of the CMP polishing liquid.

The CMP polishing liquid of the invention can increase the polishing speed for silicon oxide films and silicon nitride films with respect to the polishing speed for polysilicon films, and can be applied in a polishing step for polishing of a silicon oxide film and silicon nitride film using a polysilicon film as a stopper film.

The CMP polishing liquid of the invention may comprise a basic compound having a pKa of 8 or greater, as the pH regulator.

The CMP polishing liquid of the invention preferably comprises a nonionic surfactant as the surfactant. This can further increase the polishing speed for silicon oxide films and silicon nitride films with respect to the polishing speed for polysilicon films.

The CMP polishing liquid of the invention preferably comprises cerium oxide particles as the cerium-based abrasive grains. Also, preferably, the CMP polishing liquid of the invention comprises cerium oxide particles as the cerium-based abrasive grains, wherein the mean particle size of the cerium-based abrasive grains is 0.01-2.0 μm.

The CMP polishing liquid of the invention preferably comprises a polyacrylic acid-based dispersant as the dispersant. This can further increase the polishing speed for silicon oxide films and silicon nitride films with respect to the polishing speed for polysilicon films.

The invention further provides a method for polishing a substrate, comprising a polishing step in which a film to be polished of a substrate having the film to be polished formed on at least one side thereof, is pressed against an abrasive cloth on a polishing platen, and the film to be polished is polished by relatively moving the substrate and the polishing platen while supplying the aforementioned CMP polishing liquid between the film to be polished and the abrasive cloth.

The invention further provides a method for polishing a substrate comprising a polishing solution preparation step in which a CMP polishing liquid is obtained by mixing a first solution comprising cerium-based abrasive grains, a dispersant and water, and a second solution comprising a polyacrylic acid compound, a surfactant, a pH regulator, at least one phosphoric acid compound of phosphoric acid and a phosphoric acid derivative, and water, the pH of the second solution being 6.5 or higher, wherein the phosphoric acid compound content is 0.01-1.0 mass % based on the total mass of the CMP polishing liquid, and a polishing step in which the CMP polishing liquid is used for polishing of a film to be polished of a substrate having the film to be polished formed on at least one side thereof.

The method for polishing a substrate according to the invention can increase the polishing speed for silicon oxide films and silicon nitride films with respect to the polishing speed for polysilicon films, and can be applied in a polishing step for polishing of a silicon oxide film and silicon nitride film using a polysilicon film as a stopper film.

In the method for polishing a substrate of the invention, the pH of the first solution is preferably 7.0 or higher. In the method for polishing a substrate of the invention, the aforementioned one side of the substrate may have a step height. In the method for polishing a substrate according to the invention, a polysilicon film may be formed between the substrate and the film to be polished, and the film to be polished may be polished during the polishing step using the polysilicon film as a stopper film. Also, in the method for polishing a substrate according to the invention, at least one of the silicon oxide film and the silicon nitride film may be formed on the substrate as the film to be polished.

The invention provides an electronic component comprising a substrate polished by the method for polishing a substrate described above. Such an electronic component of the invention has excellent quality suited for micronized processing, because it comprises a substrate that allows the polishing speed for the silicon oxide film and silicon nitride film to be increased with respect to the polishing speed for the polysilicon film.

### Advantageous Effects of Invention

The CMP polishing liquid of the invention, and the method for polishing a substrate using the CMP polishing liquid, allow the polishing speed for silicon oxide films and silicon nitride films to be polished at a sufficiently practical speed while limiting the polishing speed for polysilicon films, and they can be applied in a polishing step for polishing of a silicon oxide film and silicon nitride film using a polysilicon film as a stopper film. In addition, an electronic component comprising a substrate polished by the polishing method of the invention has excellent quality suited for micronized processing.

### BRIEF DESCRIPTION OF DRAWINGS

FIG. 1 is a schematic cross-sectional view showing a polishing method according to an embodiment of the invention.

FIG. 2 is a schematic cross-sectional view showing a pattern wafer used in the examples.

### DESCRIPTION OF EMBODIMENTS

(CMP Polishing Liquid)

The CMP polishing liquid of this embodiment comprises cerium-based abrasive grains, a dispersant, a polyacrylic acid compound, a surfactant, a pH regulator, at least one phosphoric acid compound of phosphoric acid and a phosphoric acid derivative, and water. The CMP polishing liquid of this embodiment can be obtained by mixing a slurry (first solution) and an addition solution (second solution).

### (Slurry)

The slurry will be explained first. The slurry comprises cerium-based abrasive grains, a dispersant and water. The slurry preferably has the cerium-based abrasive grains dispersed in water by the dispersant.

### <Cerium-Based Abrasive Grains>

Cerium-based abrasive grains are defined as abrasive grains containing cerium as a constituent element. The CMP polishing liquid of this embodiment preferably comprises at least one type of abrasive grains selected from among cerium oxide, cerium hydroxide, cerium ammonium nitrate, cerium acetate, cerium sulfate hydrate, cerium bromate, cerium bromide, cerium chloride, cerium oxalate, cerium nitrate and cerium carbonate as cerium-based abrasive grains, it more preferably comprises cerium oxide particles, and it even more preferably consists of cerium oxide particles. There are no particular restrictions on the method of forming the cerium oxide particles, and for example, a method of firing or oxidation by hydrogen peroxide and the like may be used. The cerium oxide particles may be obtained by oxidation of a cerium compound such as a carbonate, nitrate, sulfate or oxalate. The temperature for the firing is preferably 350-900° C.

The cerium-based abrasive grains preferably include polycrystalline cerium-based abrasive grains with grain boundaries. Because such polycrystalline cerium-based abrasive grains successively present active surfaces as they are broken during polishing, it is possible to maintain a high polishing speed for the silicon oxide film.

The crystallite diameter of the cerium-based abrasive grains is preferably 1-400 nm. The crystallite diameter can be measured by a TEM photograph image or an SEM image. With a cerium oxide slurry used for polishing of a silicon oxide film formed by TEOS-CVD or the like (hereunder referred to simply as “slurry”), it is possible to achieve higher-speed polishing with larger crystallite diameters of the cerium oxide particles and smaller crystal strain, i.e. with better crystallinity. The crystallite diameter is the size of a single crystal grain of the cerium-based abrasive grain, and for polycrystals with grain boundaries it is the size of a single particle composing the polycrystals.

When the cerium-based abrasive grains are aggregated, they are preferably subjected to mechanical pulverization. The grinding method is preferably, for example, dry grinding using a jet mill and the like or wet grinding using a planetary bead mill and the like. The jet mill used may be, for example, the one described in “Kagaku Kougaku Ronbunshu”, Vol. 6, No. 5 (1980), p. 527-532.

The cerium-based abrasive grains are dispersed in water which is a dispersing medium, to obtain a slurry. The dispersion method may employ a dispersant as described below, and it may employ a homogenizer, ultrasonic disperser, wet ball mill or the like in addition to dispersion treatment by a common stirrer, for example.

Examples of methods for further micronizing the cerium-based abrasive grains dispersed by the method described above include precipitating classification methods in which a slurry is forcibly precipitated after centrifugal separation with a small centrifugal separator, and the supernatant liquid alone is removed. As a method of micronization, a high-pressure homogenizer may be used for high-pressure impact between the cerium-based abrasive grains in the dispersing medium.

The mean particle size of the cerium-based abrasive grains in the slurry is preferably 0.01-2.0 μm, more preferably 0.08-0.5 μm and even more preferably 0.08-0.4 μm. Also, preferably, the CMP polishing liquid of this embodiment comprises cerium oxide particles, wherein the mean particle size of the cerium-based abrasive grains is 0.01-2.0 μm. If the mean particle size is 0.01 μm or greater, the polishing speed for the silicon oxide film and silicon nitride film can be further increased. If the mean particle size is not greater than 2.0 μm, it will be possible to minimize polishing damage on the film to be polished.

The mean particle size of the cerium-based abrasive grains represents the median diameter of the volume distribution, measured using a laser diffraction particle size distribution meter. Specifically, the mean particle size can be obtained using an LA-920 (trade name) by Horiba, Ltd, for example. First, a sample containing cerium-based abrasive grains (either a slurry or a CMP polishing liquid) is diluted or concentrated so that a transmittance (H) during measurement with a He—Ne laser is adjusted to 60-70%, to obtain a measuring sample. Measurement is conducted after loading the measuring sample into the LA-920, and the value of the arithmetic mean diameter (mean size) is recorded.

The cerium-based abrasive grain content is preferably 0.2-3.0 mass %, more preferably 0.3-2.0 mass % and even more preferably 0.5-1.5 mass %, based on the total mass of the CMP polishing liquid. If the cerium-based abrasive grain content is 3.0 mass % or lower, the effect of modifying the polishing speed of the addition solution will be further increased. If the cerium-based abrasive grain content is 0.2 mass % or greater, the silicon oxide film polishing speed will be further increased and it will be easier to obtain the desired polishing speed.

### <Dispersant>

The dispersant used in the CMP polishing liquid of this embodiment has no further restrictions beyond being a compound that can dissolve in water and that can disperse the cerium-based abrasive grains. A dispersant is generally preferred to be a compound having a solubility of 0.1-99.9 mass % in water, examples include water-soluble anionic dispersants, water-soluble nonionic dispersants, water-soluble cationic dispersants and water-soluble amphoteric dispersants, with the polycarboxylic acid-type polymer dispersants mentioned below being preferred.

Examples of such water-soluble anionic dispersants include triethanolamine lauryl sulfate, ammonium lauryl sulfate, triethanolamine polyoxyethylene alkyl ether sulfate and polycarboxylic acid-type polymer dispersants.

Examples of polycarboxylic acid-type polymer dispersants include polymers of carboxylic acid monomer with unsaturated double bonds, such as acrylic acid, methacrylic acid, maleic acid, fumaric acid and itaconic acid, copolymers of carboxylic acid monomers with unsaturated double bonds and other monomers with unsaturated double bonds, and their ammonium salts or amine salts. Preferred as polycarboxylic acid-type polymer dispersants are polyacrylic acid-based dispersants, and more preferred are polymer dispersants having a structural unit of an ammonium acrylate salt as the copolymerizing component.

Preferred examples of polymer dispersants having a structural unit of an ammonium acrylate salt as the copolymerizing component include ammonium polyacrylate salts, and ammonium salts of copolymers of alkyl acrylates and acrylic acid. There may also be used two or more dispersants comprising at least one type of polymer dispersant having a structural unit of an ammonium acrylate salt as the copolymerizing component, and at least one other type of dispersant.

The weight-average molecular weight of the polycarboxylic acid-type polymer dispersant is preferably not greater than 100000. The weight-average molecular weight can be measured by GPC under the following conditions, for example.

### (Conditions)

### Sample: 10 μL

Standard polystyrene: Standard polystyrene by Tosoh Corp. (molecular weights: 190000, 17900, 9100, 2980, 578, 474, 370, 266)
Detector: RI-monitor by Hitachi, Ltd., trade name: “L-3000”
Integrator: GPC integrator by Hitachi, Ltd., trade name: “D-2200”
Pump: Trade name “L-6000” by Hitachi, Ltd.
Degassing apparatus: Trade name “Shodex DEGAS” by Showa Denko K.K.
Column: Trade names “GL-R440”, “GL-R430” and “GL-R420” by Hitachi Chemical Co., Ltd., linked in that order.

### Eluent: Tetrahydrofuran (THF)

Measuring temperature: 23° C.
Flow rate: 1.75 mL/min
Measuring time: 45 minutes

Examples of water-soluble nonionic dispersants include polyoxyethylene lauryl ether, polyoxyethylene cetyl ether, polyoxyethylene stearyl ether, polyoxyethylene oleyl ether, polyoxyethylene higher alcohol ethers, polyoxyethylene octylphenyl ether, polyoxyethylene nonylphenyl ether, polyoxyalkylene alkyl ethers, polyoxyethylene derivatives, polyoxyethylene sorbitan monolaurate, polyoxyethylene sorbitan monopalmitate, polyoxyethylenesorbitan monostearate, polyoxyethylene sorbitan tristearate, polyoxyethylene sorbitan monooleate, polyoxyethylene sorbitan trioleate, polyoxyethylene sorbit tetraoleate, polyethyleneglycol monolaurate, polyethyleneglycol monostearate, polyethyleneglycol distearate, polyethyleneglycol monooleate, polyoxyethylenealkylamines, polyoxyethylene hydrogenated castor oil, 2-hydroxyethyl methacrylate and alkylalkanolamides.

Examples of water-soluble cationic dispersants include polyvinylpyrrolidone, coconut amine acetate and stearylamine acetate.

Examples of water-soluble amphoteric dispersants include laurylbetaine, stearylbetaine, lauryldimethylamine oxide and 2-alkyl-N-carboxymethyl-N-hydroxyethylimidazolinium betaine.

A variety of the dispersants above may be used alone or in combinations of two or more. A CMP polishing liquid obtained by mixing a slurry and an addition solution may employ a dispersant that is the same substance as the polyacrylic acid compound or surfactant. In this case, the CMP polishing liquid obtained by mixing the slurry and the addition solution comprises the slurry-derived substance and the addition solution-derived substance.

The content of the dispersant in the slurry is preferably 1.0-5.0 mass % and more preferably 1.0-4.0 mass % based on the total mass of the abrasive grains in the slurry, as this will allow adequate dispersion of the abrasive grains and will prevent aggregation and sedimentation during storage.

When a CMP polishing liquid is to be used for polishing for production of a semiconductor element, for example, the content of impurity ions (alkali metals such as sodium ion or potassium ion, halogen atoms, sulfur atoms and the like) in the entire dispersant is preferably limited to not greater than 10 ppm as the mass ratio based on the total CMP polishing liquid.

<Slurry pH>
The slurry pH is preferably 7.0 or higher, more preferably 7.0-12.0 and even more preferably 7.0-11.0. If the pH is at least 7.0, it will be possible to prevent aggregation of the particles. If the pH is not higher than 12.0, it will be possible to obtain satisfactory flatness.

### <Water>

For the CMP polishing liquid of this embodiment, there are no particular restrictions on the water serving as the medium used for dilution of the slurry, the addition solution or their concentrates, but it is preferably deionized water or ultrapure water. The water content is not particularly restricted and may be the content of the remainder excluding the other components.

### <Addition Solution>

The addition solution will now be explained. The addition solution comprises a polyacrylic acid compound, a surfactant, a pH regulator, at least one phosphoric acid compound of phosphoric acid and a phosphoric acid derivative, and water.

### <Polyacrylic Acid Compound>

The addition solution comprises a polyacrylic acid compound as one of the addition solution components. Polyacrylic acid compounds include polyacrylic acid formed by polymerization of acrylic acid alone, and copolymers of acrylic acid and water-soluble alkyl acrylates. Examples of polyacrylic acid compounds to be used include polyacrylic acid, copolymers of acrylic acid and methyl acrylate, copolymers of acrylic acid and methacrylic acid and copolymers of acrylic acid and ethyl acrylate, among which polyacrylic acid is preferably used. These may be used alone or in combinations of two or more.

The weight-average molecular weight of the polyacrylic acid compound is preferably not greater than 500000, and more preferably not greater than 50000. If the weight-average molecular weight is not greater than 500000, when using polyacrylic acid, for example, it will be easier for the polyacrylic acid to uniformly adsorb onto the film to be polished. The weight-average molecular weight may be measured using GPC under the same conditions as for the polycarboxylic acid-type polymer dispersant.

The polyacrylic acid compound content is preferably 0.05-2.0 mass %, more preferably 0.08-1.8 mass % and even more preferably 0.10-1.5 mass %, based on the total mass of the CMP polishing liquid. If the polyacrylic acid compound content is not greater than 2.0 mass %, it will be possible to further increase the polishing speed for silicon oxide films. If the polyacrylic acid compound content is at least 0.05 mass %, it will be possible to further improve the flatness. When a polyacrylic acid compound is used as the dispersant, the total amount of the polyacrylic acid compound as the dispersant and the polyacrylic acid compound in the addition solution is preferably within the range specified above.

### <Surfactant>

The addition solution comprises a surfactant as one of the addition solution components. Surfactants include anionic surfactants, nonionic surfactants, cationic surfactants and amphoteric ionic surfactants. These may be used alone or in combinations of two or more. A nonionic surfactant is especially preferred among these surfactants.

Examples of nonionic surfactants include ether-type surfactants such as polyoxypropylene, polyoxyethylene alkyl ethers, polyoxyethylene alkyl ethers, polyoxyethylene alkyl allyl ethers, polyoxyethylene-polyoxypropylene ether derivatives, polyoxypropylene glyceryl ether, polyethylene glycol, methoxypolyethylene glycol, and ether-type surfactants such as oxyethylene adducts of acetylene-based diols; ester-type surfactants such as sorbitan fatty acid esters and glycerol borate fatty acid esters; aminoether-type surfactants such as polyoxyethylenealkylamines; ether ester-type surfactants such as polyoxyethylene sorbitan fatty acid esters, polyoxyethyleneglycerol borate fatty acid esters and polyoxyethylene alkyl esters; alkanolamide-type surfactants such as fatty acid alkanolamides and polyoxyethylene fatty acid alkanolamides; oxyethylene adducts of acetylene-based diols; polyvinylpyrrolidones; polyacrylamides; polydimethylacrylamides; and the like.

The surfactant content is preferably 0.01-1.0 mass %, more preferably 0.02-0.7 mass % and even more preferably 0.03-0.5 mass %, based on the total mass of the CMP polishing liquid. If the surfactant content is not greater than 1.0 mass %, the polishing speed for silicon oxide films will be further increased. If the surfactant content is at least 0.01 mass %, it will be possible to further prevent increase in the polishing speed for polysilicon films. When a surfactant is used as the dispersant, the total amount of the surfactant as the dispersant and the surfactant in the addition solution is preferably within the range specified above.

<Addition Solution pH>
The addition solution pH needs to be 6.5 or higher, and it is preferably 6.7-12.0 and more preferably 6.8-11.0. If the pH is 6.5 or higher, it will be possible to prevent aggregation of the particles in the slurry when the addition solution and the slurry have been mixed. If the pH is not higher than 12.0, it will be possible to obtain satisfactory flatness when the addition solution and the slurry have been mixed.

The pH of the addition solution may be measured with a pH meter, using a common glass electrode. Specifically, the pH measurement may be conducted using, for example, a Model F-51, trade name of Horiba, Ltd. The pH of the addition solution can be obtained by placing the electrodes of the pH meter in the addition solution after 3-point calibration of the pH meter using phthalate pH standard solution (pH: 4.01), neutral phosphate pH standard solution (pH: 6.86) and borate pH standard solution (pH: 9.18) as the pH standard solutions, and measuring the value after stabilization following an elapse of 2 minutes or longer. The solution temperatures of the standard buffer and addition solution during this time may both be 25° C., for example. The slurry pH can also be measured by the same method.

### <pH Regulator>

The CMP polishing liquid of this embodiment comprises a pH regulator as one of the addition solution components. The pH regulator may be a water-soluble basic compound or a water-soluble acidic compound. Basic compounds include basic compounds with pKa values of 8 or greater. Here, “pKa” is the acid dissociation constant for the first dissociable acidic group, and it is the negative common logarithm of the equilibrium constant Ka of the group. Specifically, the basic compound is preferably a water-soluble organic amine, ammonia water, or the like. The addition solution pH may be adjusted by the other components such as the polyacrylic acid compound.

Examples of water-soluble organic amines include ethylamine, diethylamine, triethylamine, diphenylguanidine, piperidine, butylamine, dibutylamine, isopropylamine, tetramethylammonium oxide, tetramethylammonium chloride, tetramethylammonium bromide, tetramethylammonium fluoride, tetrabutylammonium hydroxide, tetrabutylammonium chloride, tetrabutylammonium bromide, tetrabutylammonium fluoride, tetramethylammonium nitrate, tetramethylammonium acetate, tetramethylammonium propionate, tetramethylammonium malate and tetramethylammonium sulfate.

The pH regulator content, for example, when using a basic compound, is preferably 0.01-10.0 mass %, more preferably 0.05-5.0 mass % and even more preferably 0.1-3.0 mass %, based on the total mass of the CMP polishing liquid. However, since the pH regulator content is limited by the pH to be adjusted, it is determined by the contents of the other components (strong acid, polyacrylic acid compound and the like), and is not particularly restricted.

### <Phosphoric Acid Compound>

The addition solution comprises at least one phosphoric acid compound of phosphoric acid and a phosphoric acid derivative, as one of the addition solution components. The term “phosphoric acid compound” includes phosphoric acid and phosphoric acid derivatives. Examples of phosphoric acid derivatives include phosphoric acid polymers including dimers and trimers (for example, pyrophosphoric acid, pyrophosphorous acid and trimetaphosphoric acid), or compounds containing phosphate groups (for example, sodium hydrogenphosphate, sodium phosphate, ammonium phosphate, potassium phosphate, calcium phosphate, sodium pyrophosphate, polyphosphoric acid, sodium polyphosphate, metaphosphoric acid, sodium metaphosphate and ammonium phosphate).

The phosphoric acid compound content is 0.01-1.0 mass %, preferably 0.02-0.7 mass % and more preferably 0.03-0.5 mass %, based on the total mass of the CMP polishing liquid. If the phosphoric acid compound content is not greater than 1.0 mass %, it will be possible to further increase the polishing speed for silicon nitride films. Likewise, if the phosphoric acid compound content is at least 0.01 mass %, it will be possible to further increase the polishing speed for silicon nitride films. When phosphoric acid and a phosphoric acid derivative are both used as phosphoric acid compounds, their total content is preferably within the range specified above.

(CMP Polishing Liquid Storage Method)

The CMP polishing liquid of this embodiment is preferably stored as a 2-pack polishing solution divided into, for example, a slurry comprising cerium-based abrasive grains dispersed with a dispersant in water, and an addition solution. If a 2-pack polishing solution is stored without mixture of the slurry and additive, it is possible to inhibit aggregation of the cerium-based abrasive grains and minimize variation in the polishing damage-inhibiting effect and the polishing speed.

The slurry and the addition solution may be mixed beforehand, or mixed immediately before use. When a 2-pack polishing solution is used, the method employed may be, for example, method A in which the slurry and addition solution are conveyed through separate tubings and the tubings are merged for mixture just prior to the supply tubing exit, and supplied onto a polishing platen, method B in which the slurry and addition solution are mixed just prior to polishing, method C in which the slurry and additive are separately supplied to the polishing platen and the two solutions are mixed on the polishing platen, and method D in which a prepared mixture of the slurry and the addition solution is supplied through supply tubing. By changing the composition of the two solutions as desired, it is possible to adjust the flattening property and the polishing speed. The mixing ratio for the slurry and addition solution is preferably about 1:10-10:1 (slurry:addition solution) as the mass ratio. For method A or method B, a concentrate of the slurry or addition solution with reduced water content is prepared beforehand, and is diluted with deionized water as necessary at the time of mixture.

### (Method for Polishing Substrate)

The method for polishing a substrate according to this embodiment comprises a polishing step in which a film to be polished of a substrate having the film to be polished formed on at least one side thereof, is pressed against an abrasive cloth on a polishing platen, and the film to be polished is polished by relatively moving the substrate and the polishing platen while supplying the aforementioned CMP polishing liquid between the film to be polished and the abrasive cloth. The method for polishing a substrate according to this embodiment may also comprise a polishing solution preparation step in which the slurry and the addition solution are mixed to obtain the CMP polishing liquid, and a polishing step in which the obtained CMP polishing liquid is used for polishing of a film to be polished of the substrate having the film to be polished formed on at least one side thereof.

When one side of a substrate on which a film to be polished is formed has a step height, the method for polishing a substrate of this embodiment is particularly suitable as a polishing step for flattening of the step height by polishing the one side of the substrate.

In the method for polishing a substrate according to this embodiment, when a polysilicon film has been formed between the substrate and the film to be polished, the film to be polished may be polished during the polishing step using the polysilicon film as a stopper film. For example, a stopper film may be formed along the separating groove of a substrate on which the separating groove has been formed, and the film to be polished formed on the stopper film, then the film to be polished may be removed until the stopper film is exposed.

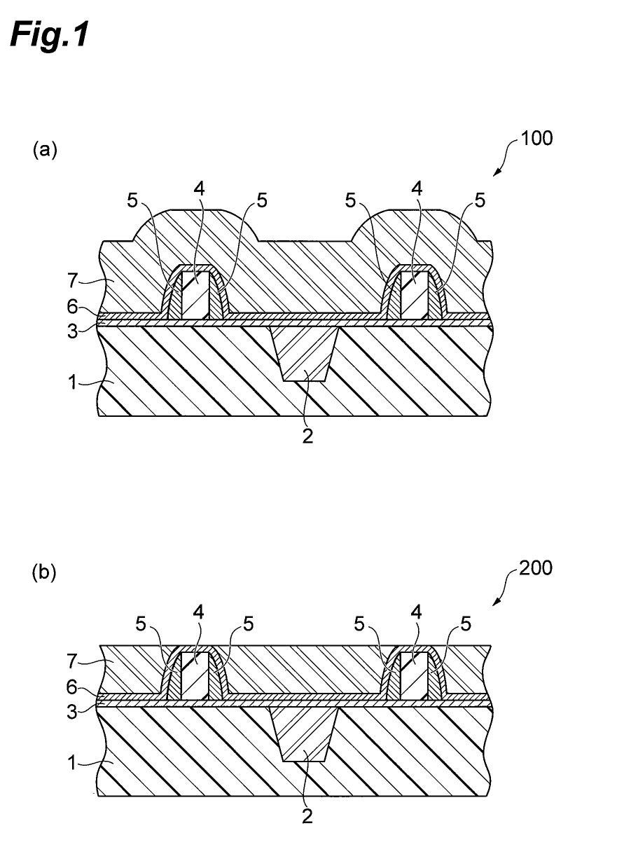

More specifically, it may be a polishing method for polishing of a substrate 100 having the structure shown in FIG. 1(a). The substrate 100 shown in FIG. 1(a) has an insulator 2 such as silicon dioxide embedded in a groove formed on silicon 1, for formation of shallow trench isolation (STI). An insulating film 3 with high electric conductivity (high-k insulating film) is laminated on the silicon 1. At a prescribed position on the insulating film 3 there is formed a dummy gate 4 of the polysilicon film, and on the side of the dummy gate 4 there is formed a side wall 5 of the silicon nitride film. Also, a stress liner 6 of the silicon nitride film is laminated covering the surface, to improve the transistor performance by applying stress to the diffusion layer, and finally the silicon oxide film 7 is laminated thereover. A portion of the silicon oxide film 7 of the substrate and the stress liner 6 of the silicon nitride is polished using the CMP polishing liquid of this embodiment until the polysilicon dummy gate 4 is exposed, thereby yielding a substrate 200 having the structure shown in FIG. 1(b). In this step, the polysilicon film as the dummy gate 4 acts as a stopper film to minimize excess polishing.

A method of polishing will be further described, for an example of a semiconductor substrate on which there is formed an inorganic insulating layer of either or both a silicon oxide film or a silicon nitride film, as the film to be polished.

The polishing apparatus to be used in the polishing method of this embodiment may be, for example, a common polishing apparatus comprising a holder that holds the substrate with the film to be polished, and a polishing platen which allows attachment of an abrasive cloth (pad) and mounts a motor having a variable rotational speed.

Examples of such polishing apparatuses include the model EPO-111 polishing apparatus by Ebara Corp., and trade name Mirra3400 and Reflection polishing machines which are polishing apparatuses by AMAT (Applied Materials).

There are no particular restrictions on the abrasive cloth, and for example, a common nonwoven fabric, foamed polyurethane, porous fluorine resin or the like may be used. The abrasive cloth is preferably furrowed to allow accumulation of the polishing solution.

The polishing conditions are not particularly restricted, but from the viewpoint of minimizing fly off of the semiconductor substrate, the rotational speed of the polishing platen is preferably a low speed of not greater than 200 rpm. The pressure (machining load) on the semiconductor substrate is preferably not greater than 100 kPa, from the viewpoint of minimizing damage after polishing.

The polishing solution is preferably continuously supplied to the surface of the abrasive cloth with a pump during polishing. The amount supplied is not restricted, but preferably the surface of the abrasive cloth is covered by the polishing solution at all times.

The method of supplying the polishing solution may be, as mentioned above, method A in which two solutions are conveyed through separate tubings and the tubings are merged for mixture just prior to the supply tubing exit, and supplied onto a polishing platen, method B in which the two solutions are mixed just prior to polishing, method C in which the two solutions are separately supplied to the polishing platen, and method D in which a prepared mixture of the slurry and the addition solution is supplied through supply tubing.

The polished semiconductor substrate is preferably thoroughly rinsed in running water, and then the water droplets adhering to the semiconductor substrate are removed off using a spin dryer or the like, prior to drying. Polishing of the inorganic insulating layer, as the film to be polished, using the polishing solution in this manner allows irregularities on the surface to be eliminated, to obtain a smooth surface across the entire semiconductor substrate. By repeating this step a prescribed number of times, it is possible to produce a semiconductor substrate having the desired number of layers.

The method of forming the silicon oxide film and silicon nitride film as films to be polished may be a low-pressure CVD method, a plasma CVD method, or the like. When a silicon oxide film is formed by a low-pressure CVD method, monosilane (SiH₄) may be used as the Si source and oxygen (O₂) as the oxygen source. The silicon oxide film may be obtained by SiH₄—O₂-based oxidation reaction conducted at a low temperature of not higher than 400° C. The silicon oxide film may be formed by a CVD method, and then subjected to heat treatment at a temperature of 1000° C. or below, depending on the case.

The silicon oxide film may be doped with an element such as phosphorus or boron. When the silicon oxide film is doped with phosphorus (P) in order to achieve surface flattening with high-temperature reflow, a SiH₄—O₂—PH₃-based reactive gas is preferably used.

Plasma CVD has the advantage of allowing a chemical reaction that requires high temperature at normal thermal equilibrium to take place at low temperature. Plasma generation methods include capacitive coupling and inductive coupling types. The reactive gas may be a SiH₄—N₂O-based gas with SiH₄ as the Si source and N₂O as the oxygen source, or a TEOS-O₂-based gas with tetraethoxysilane (TEOS) as the Si source (TEOS-plasma CVD). The substrate temperature is preferably 250-400° C. and the reaction pressure is preferably 67-400 Pa.

When a silicon nitride film is formed by a low-pressure CVD method, dichlorsilane (SiH₂Cl₂) may be used as the Si source and ammonia: (NH₃) may be used as the nitrogen source. The silicon nitride film may be obtained by SiH₂Cl₂—NH₃-based oxidation reaction at a high temperature of 900° C.

In plasma CVD, the reactive gas may be a SiH₄—NH₃-based gas with SiH₄ as the Si source and NH₃ as the nitrogen source. The substrate temperature is preferably 300-400° C.

The substrate used for this embodiment may be a substrate comprising a discrete semiconductor such as a diode, transistor, compound semiconductor, thermistor, varistor or thyristor, a memory element such as DRAM (Dynamic Random Access Memory), SRAM (Static Random Access Memory), EPROM (Erasable Programmable Read-Only Memory), Mask ROM (Mask Read-Only Memory), EEPROM (Electrically Erasable Programmable Read-Only Memory) or Flash Memory, a logic circuit element such as a microprocessor, DSP or ASIC, an integrated circuit element such as a compound semiconductor, an example of which is an MMIC (Monolithic Microwave Integrated Circuit), a hybrid integrated circuit (hybrid IC), or a photoelectric conversion element such as a light emitting diode or charge-coupled element.

The CMP polishing liquid of this embodiment allows polishing not only of silicon nitride films and silicon oxide films formed on semiconductor substrates, but also of inorganic insulating films of silicon oxide, glass or silicon nitride, and films composed mainly of polysilicon, Al, Cu, Ti, TiN, W, Ta, TaN or the like, that are formed on circuit boards with prescribed wirings.

### (Electronic Component)

The electronic component of this embodiment employs a substrate that has been polished by the polishing method described above. The term “electronic component” includes not only semiconductor elements, but also optical glass such as photomask lens prisms; inorganic conductive films such as ITO; integrated optical circuits, optical switching elements and optical waveguides composed of glass and crystalline materials; optical fiber tips; optical single crystals such as scintillators; solid laser single crystals; sapphire substrates for blue laser LED; semiconductor single crystals such as SiC, GaP and GaAs; glass panels for magnetic disk; magnetic heads; and the like.

### EXAMPLES

The present invention will now be explained through the examples, with the understanding that the invention is in no way limited by the examples.

### (Fabrication of Pulverized Cerium Oxide Powder)

After placing 40 kg of cerium carbonate hydrate in an alumina container, it was fired at 830° C. for 2 hours in air to obtain 20 kg of yellowish white powder. The powder was subjected to phase identification by X-ray diffraction, by which it was identified as cerium oxide. As a result of measuring the particle size of the fired powder with a laser diffraction-type particle size distribution meter, the particle size of the fired powder was found to be at least 95% distributed between 1-100 μm.

Next, 20 kg of cerium oxide powder was subjected to dry grinding using a jet mill. The specific surface area of the polycrystals was measured by the BET method to be 9.4 m²/g.

### (Preparation of Cerium Oxide Slurry)

After mixing 10.0 kg of cerium oxide powder and 116.65 kg of deionized water, 228 g of a commercially available aqueous ammonium polyacrylate salt solution (weight-average molecular weight: 8000, 40 mass %) was added as a dispersant, to obtain a cerium oxide dispersion. After stirring the cerium oxide dispersion for 10 minutes, it was conveyed to a separate container while conducting ultrasonic irradiation in the conveyance tubing. The ultrasonic frequency was 400 kHz, and the cerium oxide dispersion was conveyed over a period of 30 minutes.

The conveyed cerium oxide dispersion was then divided into four 500 mL beakers in 500 g±20 g portions, and centrifuged. Centrifugal separation was carried out for 2 minutes under conditions with an outer peripheral centrifugal force of 500 G, and the cerium oxide deposited on the bottom of the beaker was removed.

The solid concentration of the obtained cerium oxide dispersion (cerium oxide slurry) was measured to be 4.0 mass %. The slurry pH was measured to be 9.0.

Also, using a laser diffraction-type particle size distribution meter [LA-920, trade name of Horiba, Ltd.], the mean particle size of the cerium oxide particles in the slurry were measured with a refractive index of 1.93 and a permeability of 68% and it was found to be 0.11 μm.

The impurity ions (Na, K, Fe, Al, Zr, Cu, Si, Ti) in the cerium oxide slurry were present at a mass ratio of not greater than 1 ppm, as measured using an atomic absorption photometer [trade name: AA-6650 by Shimadzu Corp.].

### (Preparation of Addition Solution)

### Example 1

An addition solution was prepared by the following steps.

A 900 g portion of ultrapure water was weighed out into a 1000 mL container a.

A 10.0 g portion of a 40 mass % polyacrylic acid aqueous solution (weight-average molecular weight: 3000) was then placed in the container a.

A 15.0 g portion of a surfactant, polyethoxylate of 2,4,7,9-tetramethyl-5-decyne-4,7-diol, was subsequently placed in the container a.

A 85 mass % phosphoric acid aqueous solution was placed in the container a so that 8.5 g of phosphoric acid was placed.

Ammonia water (25 mass % aqueous solution) was placed in the container a while the additive amount was adjusted to the addition solution pH of 7.0.

Ultrapure water was added in an appropriate amount to prepare a total 1000 g of an addition solution.

### Examples 2-11

Addition solutions were prepared in the same manner as Example 1, with the contents listed in Table 1.

### Comparative Examples 1-7

Addition solutions were prepared in the same manner as Example 1, with the contents listed in Table 2.

### (Preparation of Polishing Solutions)

There were mixed 500 g of the cerium oxide slurry, 500 g of each addition solution prepared in Examples 1-11 or Comparative Examples 1-7, and 1500 g of purified water, to prepare total 2500 g of each CMP polishing liquid, respectively.

TABLE 1

| | | Example | | | | | | | | | | |
|---|---|---|---|---|---|---|---|---|---|---|---|---|
| Component | Attribute | 1 | 2 | 3 | 4 | 5 | 6 | 7 | 8 | 9 | 10 | 11 |
| Polyacrylic acid | Type | Polyacrylic acid aqueous solution (40 mass %) | | | | | | | | | | |
| compound | Weight-average | 3000 | | | | | | | | | | |
| | molecular weight | | | | | | | | | | | |
| | Content (g) | 10 | 15 | 20 | 10 | 10 | 10 | 10 | 10 | 10 | 10 | 10 |
| Surfactant | Type | *1 | | | *2 | *3 | *4 | *1 | | | | |
| | Content (g) | 15 | 15 | 15 | 15 | 15 | 15 | 30 | 15 | 15 | 15 | 15 |
| pH regulator | Type | Ammonia water (25 mass % aqueous solution) | | | | | | | | | | KOH |
| | Content (g) | Adjusted to pH listed below | | | | | | | | | | |
| Phosphoric acid | Type | Phosphoric acid | | | | | | | | | | |
| compound | Content (g) | 8.5 | 8.5 | 8.5 | 8.5 | 8.5 | 8.5 | 8.5 | 8.5 | 12.5 | 25.5 | 8.5 |
| Water | Content (g) | Remainder after removal of 4 components (Total of 4 components and water: 1000 g) | | | | | | | | | | |
| Addition solution pH | | 7.0 | 7.0 | 7.0 | 7.0 | 7.0 | 7.0 | 7.0 | 8.0 | 7.0 | 7.0 | 7.0 |
| Polishing speed | Silicon oxide film | 2750 | 2800 | 2600 | 2700 | 2800 | 2750 | 2650 | 2650 | 2850 | 2550 | 2800 |
| (Å/min) | Silicon nitride film | 1000 | 1050 | 900 | 1050 | 1000 | 950 | 1000 | 950 | 950 | 700 | 1050 |
| | Polysilicon film | 25 | 30 | 30 | 35 | 30 | 30 | 25 | 35 | 30 | 40 | 35 |
| Polishing speed | Silicon oxide | 110 | 93 | 87 | 77 | 93 | 92 | 106 | 76 | 95 | 64 | 80 |
| ratio | film/polysilicon film | | | | | | | | | | | |
| | Silicon nitride | 40 | 35 | 30 | 30 | 33 | 32 | 40 | 27 | 32 | 18 | 30 |
| | film/polysilicon film | | | | | | | | | | | |
| Pattern wafer A | Residual thickness of | None | None | None | None | None | None | None | None | None | None | None |
| evaluation | silicon nitride film | | | | | | | | | | | |
| | after polishing | | | | | | | | | | | |
| Pattern wafer B | Flatness (Å) | 280 | 220 | 180 | 250 | 320 | 380 | 370 | 230 | 320 | 280 | 300 |
| evaluation | | | | | | | | | | | | |

*1: Polyethoxylate of 2,4,7,9-Tetramethyl-5-decyne-4,7-diol
*2: Polyoxyethylene sorbitan monopalmitate
*3: Polyoxyethylene sorbitan monostearate
*4: Polyethylene glycol (weight-average molecular weight: 4000)

TABLE 2

| | | Comp. Ex. | | | | | | |
|---|---|---|---|---|---|---|---|---|
| Component | Attribute | 1 | 2 | 3 | 4 | 5 | 6 | 7 |
| Polyacrylic acid | Type | — | Polyacrylic acid aqueous solution (40 mass %) | | | | | |
| compound | Weight-average molecular weight | — | 3000 | | | | | |
| | Content (g) | — | 10 | 10 | 10 | 10 | 10 | 10 |
| Surfactant | Type | *1 | | | | | | — |
| | Content (g) | 15 | 15 | 15 | 15 | 15 | 15 | — |
| pH regulator | Type | Ammonia water (25 mass % aqueous solution) | | | | | | |
| | Content (g) | Adjusted to pH listed below | | | | | | |
| Phosphoric acid | Type | — | — | Sulfuric acid | Phosphoric acid | | | |
| compound | Content (g) | — | — | 8.5 | 8.5 | 8.5 | 51.0 | 8.5 |
| Water | Content (g) | Remainder after removal of 4 components (Total of 4 components and water: 1000 g) | | | | | | |
| Addition solution pH | | 7.0 | 7.0 | 7.0 | 5.0 | 6.0 | 7.0 | 7.0 |
| Polishing speed | Silicon oxide film | 3200 | 2500 | 2500 | 3000 | 2900 | 2330 | 2600 |
| (Å/min) | Silicon nitride film | 600 | 200 | 150 | 200 | 300 | 550 | 950 |
| | Polysilicon film | 40 | 35 | 35 | 35 | 30 | 35 | 1050 |
| Polishing speed | Silicon oxide film/polysilicon film | 80 | 71 | 71 | 86 | 97 | 67 | 2.4 |
| ratio | Silicon nitride film/polysilicon film | 15 | 6 | 4 | 6 | 10 | 16 | 0.9 |
| Pattern wafer A | Residual thickness of silicon nitride | Remained | Remained | Remained | Remained | Remained | Remained | None |
| evaluation | film after polishing | | | | | | | |
| Pattern wafer B | Flatness (Å) | 980 | 220 | 250 | 690 | 320 | 200 | *5 |
| evaluation | | | | | | | | |

*1: Polyethoxylate of 2,4,7,9-tetramethyl-5-decyne-4,7-diol
*5: Polysilicon film excessively polished, not evaluatable

### (Polishing Evaluation)

As test wafers for evaluation of the insulating film CMP, which were blanket wafers having no pattern formed thereon, there were used a silicon oxide film of a thickness of 1000 nm formed on a Si substrate, a silicon nitride film of a thickness of 200 nm formed on a Si substrate, and a polysilicon film of a thickness of 100 nm formed on a Si substrate.

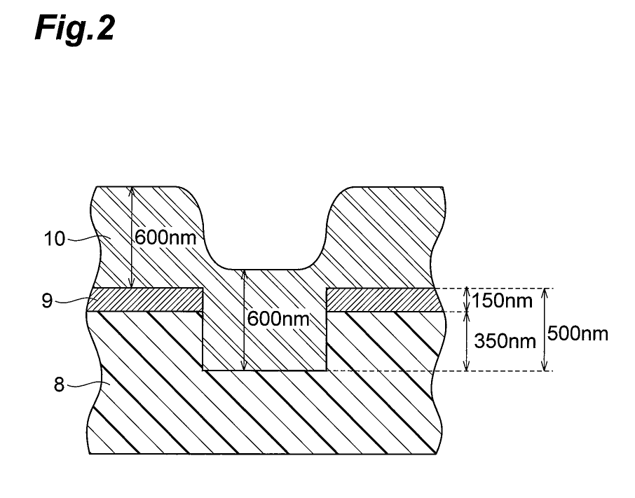

Also, an 864 wafer by Sematech (trade name, diameter: 200 mm) was used as a pattern wafer having a test pattern formed thereon. As shown in FIG. 2, the pattern wafer comprises a silicon substrate 8 having a trench on the surface, a silicon nitride film 9 laminated on the silicon substrate 8 avoiding the trench, and a silicon oxide (SiO₂) film (insulating film) 10 laminated on the silicon substrate 8 and silicon nitride film 9, filling the trench. The silicon oxide film 10 was formed by HDP (High Density Plasma), and the film thickness was 600 nm on both the silicon substrate 8 and the silicon nitride film 9. Specifically, the thickness of the silicon nitride film 9 was 150 nm, the thickness of the convexities of the silicon oxide film 10 was 600 nm, the thickness of the concavities of the silicon oxide film 10 was 600 nm, and the depth of the concavities of the silicon oxide film 10 was 500 nm (trench depth: 350 nm+silicon nitride film thickness: 150 nm). For the polishing evaluation, there was used one in a state with the silicon nitride film exposed, obtained by polishing the wafer using a known CMP polishing liquid capable of polishing silicon oxide films against silicon nitride films with sufficient selectivity (pattern wafer A).

There was used a wafer having the same construction as pattern wafer A, but having a polysilicon film formed of a thickness of 150 nm instead of the silicon nitride film (pattern wafer B).

For evaluation of the pattern wafer, there was used one having a line (convexity) and space (concavity) width with a 200 μm pitch and a convexity pattern density of 50%. The lines and spaces forms a test pattern, and comprises active sections masked by Si₃N₄ as the convexities and trench sections with grooves as the concavities, alternately arranged in a pattern. For example, a “100 μm pitch of the lines and spaces” means that the total width of the line section and space section is 100 μm. Also, a “convexity pattern density of 10%”, for example, means that the pattern has an alternating arrangement of 10 μm convexity widths and 90 μm concavity widths, and a convexity pattern density of 90% means that the pattern has an alternating arrangement of 90 μm convexity widths and 10 μm concavity widths.

The test wafer was set in a holder mounting a substrate-mounting adsorption pad, in a polishing apparatus (trade name: MIRRA3400, product of Applied Materials, Inc.). A porous urethane resin abrasive pad (Model IC-1010 by Rodel) was mounted on a polishing platen for a 200 mm wafer.

The holder was placed on the abrasive pad with the insulating film side facing downward, and the membrane pressure was set to 31 kPa.

The cerium oxide slurry was dropped onto the polishing platen at a rate of 160 mL/min and the addition solution of each of Examples 1-11 or Comparative Examples 1-7 was simultaneously dropped at a rate of 40 mL/min, while the polishing platen and wafer were actuated at 123 rpm and 113 rpm, respectively, for polishing of the blanket wafers of the silicon oxide film (P-TEOS film), the silicon nitride film and the polysilicon film, for 1 minute each.

Pattern wafers A and B were also polished for 100 seconds each.

The polished wafers were thoroughly washed with purified water and dried.

Next, the residual film thickness of each of the blanket wafers of the silicon oxide film, silicon nitride film and polysilicon film was measured at 55 points within the wafer plane using a light-interference film thickness meter (trade name: RE-3000 by Dainippon Screen Mfg. Co., Ltd.), and the polishing speed per minute was calculated from the decrease in film thickness compared to before polishing. As regards the pattern wafers, a light-interference film thickness meter (trade name: RE-3000 by Dainippon Screen Mfg. Co., Ltd.) was used to measure the residual film thickness of the silicon nitride film, for pattern wafer A, and the residual film thickness of the insulating film on the concavities and the residual film thickness of the insulating film on the convexities, for pattern wafer B. The difference of the residual film thickness between the insulating film on the convexities and the insulating film on the concavities of the pattern wafer B was recorded as the flatness.

The obtained measurement results are shown in Tables 1 and 2 above.

As shown in Tables 1 and 2, Examples 1-11 revealed the polishing speed ratio of 64-110 for silicon oxide film/polysilicon film and 18 or greater for silicon nitride film/polysilicon film, while the polishing speed for the polysilicon film was limited to not greater than 40 Å/min, thus indicating that the polishing speeds for silicon oxide film and silicon nitride film are increased while limiting the polishing speed for polysilicon film.

When Examples 1-11 and Comparative Examples 1-7 are compared, it is clear that the polishing speed for silicon nitride films, in particular, was improved in Examples 1-11. Also, the results of evaluating pattern wafer A clearly indicate that the silicon nitride films were sufficiently polished in Examples 1-11. Furthermore, the results of evaluating pattern wafer B indicate that Examples 1-11 all had low flatness values, thus indicating satisfactory flatness.

### EXPLANATION OF SYMBOLS

1: Silicon, 2: insulator, 3: insulating film, 4: dummy gate, 5: side wall, 6: stress liner, 7: silicon oxide film, 8: silicon substrate, 9: silicon nitride film, 10: silicon oxide film, 100, 200: substrates.

1. A CMP polishing liquid to be used by mixing a first solution and a second solution,
the first solution comprising cerium-based abrasive grains, a dispersant and water,
the second solution comprising a polyacrylic acid compound, a surfactant, a pH regulator, at least one phosphoric acid compound of phosphoric acid and a phosphoric acid derivative, and water,
a pH of the second solution being 6.5 or higher, and
the first solution and second solution being mixed so that a phosphoric acid compound content is 0.01-1.0 mass % based on the total mass of the CMP polishing liquid.

2. The CMP polishing liquid according to claim 1, wherein the second solution comprises a basic compound having a pKa of 8 or greater, as the pH regulator.

3. The CMP polishing liquid according to claim 1, wherein the second solution comprises a nonionic surfactant as the surfactant.

4. The CMP polishing liquid according to claim 1, wherein a pH of the first solution is 7.0 or higher.

5. The CMP polishing liquid according to claim 1, wherein the first solution comprises cerium oxide particles as the cerium-based abrasive grains.

6. The CMP polishing liquid according to claim 1, wherein the first solution comprises cerium oxide particles as the cerium-based abrasive grains, and a mean particle size of the cerium-based abrasive grains is 0.01-2.0 μm.

7. The CMP polishing liquid according to claim 1, wherein the first solution comprises a polyacrylic acid-based dispersant as the dispersant.

8. A CMP polishing liquid comprising cerium-based abrasive grains, a dispersant, a polyacrylic acid compound, a surfactant, a pH regulator, at least one phosphoric acid compound of phosphoric acid and a phosphoric acid derivative, and water,
wherein the phosphoric acid compound content is 0.01-1.0 mass % based on the total mass of the CMP polishing liquid.

9. The CMP polishing liquid according to claim 8, comprising a basic compound having a pKa of 8 or greater, as the pH regulator.

10. The CMP polishing liquid according to claim 8, comprising a nonionic surfactant as the surfactant.

11. The CMP polishing liquid according to claim 8, comprising cerium oxide particles as the cerium-based abrasive grains.

12. The CMP polishing liquid according to claim 8, comprising cerium oxide particles as the cerium-based abrasive grains, a mean particle size of the cerium-based abrasive grains being 0.01-2.0 μm.

13. The CMP polishing liquid according to claim 8, comprising a polyacrylic acid-based dispersant as the dispersant.

14. A method for polishing a substrate, comprising a polishing step in which a film to be polished of a substrate having the film to be polished formed on at least one side thereof, is pressed against an abrasive cloth on a polishing platen, and the film to be polished is polished by relatively moving the substrate and the polishing platen while supplying a CMP polishing liquid according to claim 1 between the film to be polished and the abrasive cloth.

15. A method for polishing a substrate comprising:
a polishing solution preparation step in which a CMP polishing liquid is obtained by mixing a first solution comprising cerium-based abrasive grains, a dispersant and water, and a second solution comprising a polyacrylic acid compound, a surfactant, a pH regulator, at least one phosphoric acid compound of phosphoric acid and a phosphoric acid derivative, and water, a pH of the second solution being 6.5 or higher, wherein a phosphoric acid compound content is 0.01-1.0 mass % based on the total mass of the CMP polishing liquid, and
a polishing step in which the CMP polishing liquid is used for polishing of a film to be polished of a substrate having the film to be polished formed on at least one side thereof.

16. The method for polishing a substrate according to claim 15, wherein a pH of the first solution is 7.0 or higher.

17. The method for polishing a substrate according to claim 14, wherein the one side of the substrate has a step height.

18. The method for polishing a substrate according to claim 14, wherein
a polysilicon film is formed between the substrate and the film to be polished, and
the film to be polished is polished during the polishing step using the polysilicon film as a stopper film.

19. The method for polishing a substrate according to claim 14, wherein at least one of a silicon oxide film and a silicon nitride film is formed on the substrate as the film to be polished.

20. An electronic component comprising a substrate polished by the method for polishing a substrate according to claim 14.
